(19) United States
(12) Patent Application Publication
(10) Pub. No.: US 2011/0073891 A1
(43) Pub. Date: Mar. 31, 2011

(54) AC DRIVEN LIGHT EMITTING DIODE LIGHT APPARATUS, AND ITS AC DRIVEN LIGHT EMITTING DIODE PACKAGE ELEMENT THEREIN

(75) Inventor: Chih-Chien YEN, Taipei County (TW)

(73) Assignee: STAR-REACH CORP., Taipei County (TW)

(21) Appl. No.: 12/781,715

(22) Filed: May 17, 2010

(30) Foreign Application Priority Data
Sep. 30, 2009 (TW) 98133221

(51) Int. Cl. H01L 33/62; H01L 33/64

(52) U.S. Cl. 257/98; 257/99; 257/E33.056

(57) ABSTRACT

An AC driven light emitting diode light apparatus, and its AC driven light emitting diode package element therein are provided. The AC driven light emitting diode package element includes a heat sinking substrate, a chip set, a pair of electrodes, and a package body. The heat sinking substrate has a fixing flange extended from a rim of the heat sinking substrate for fixing the heat sinking substrate on a support. The chip set is on the heat sinking substrate. The conductive electrodes are respectively set at two opposite sides of the heat sinking substrate. The package body envelops the heat sinking substrate, the chip set and a part of the conductive electrodes to be one.

### RELATED APPLICATIONS

This application claims priority to Taiwan Application Serial Number 98133221, filed Sep. 30, 2009, which is herein incorporated by reference.

### BACKGROUND

1. Technical Field

The disclosure relates to a light emitting diode device, more particularly to an alternating current driven light emitting diode device.

2. Description of Related Art

Since the optoelectronics technology is developed steadily, light emitting diodes (LED) have been widely applied in a variety of electronic fields. The LED possesses many advantages of long product life, low power consumption and small size, which are absent in the conventional lamp products such as incandescent lamps, halogen lamps and fluorescent lamps. Therefore, the conventional lamp products for illumination are gradually replaced by the LED products.

A recently launched product called “alternating current driven light emitting diode (AC driven LED in short)” provides advantages of longer product life and lower power consumption compared to the conventional LED products.

The technical concept of the AC driven LED product is to change the permutation of the LED chips arranged in the AC driven LED product in an extraordinary way, and to employ P/N electrodes of the LED chips thereof to concurrently serve as a current rectifier based on the diode characteristics of the P/N electrodes thereof, thus, the AC driven LED product can directly accept alternating current of power for operation.

Refer to FIG. 1. FIG. 1 illustrates a schematic diagram of a conventional AC driven LED package structure. The conventional AC driven LED package 10 includes a plurality of irradiating elements 11, conductive electrodes 12 and a packaging body 13 enveloping the irradiating element 11 and a part of the conductive electrodes 12, in which the conductive electrodes 12 extending outwards the packaging body 13 are welded on an electrical conductor. Furthermore, the conductive electrodes 12 extending outwards the packaging body 13 have a curving portion 121 respectively so that the curving portions 121 guide the conductive electrodes 12 to further approach the electrical conductor so as to improve the convenience of the welding process.

However, as the conventional AC driven LED package 10 goes through the welding process, many complex steps of the welding process, such as solder paste printing, solder oven passing and so on, need to be done consequently, so as to be time-consuming and labor-intensive.

On the other hand, as the conventional AC driven LED package 10 needs to be repaired or replaced after the welding process is finished, the conventional AC driven LED package 10 can be removed only if the solder pastes of the conventional AC driven LED package 10 are detached, so as to be very inconvenient. Furthermore, since the temperature of the solder oven is quite high, it raises the possibility that the conventional AC driven LED package 10 breaks down, when the conventional AC driven LED package 10 is passed through the solder oven.

In view of the mentioned prior arts, how to develop a solution of AC driven LED package for improving the mentioned disadvantages shall be concerned.

### SUMMARY

The present disclosure is to provide an AC driven light emitting diode (AC driven LED) light apparatus, and its AC driven LED package element therein. With detachably coupling the conductive electrodes of the AC driven LED package element with an AC electricity wire, the present disclosure of the AC driven LED package element replaces the assembly procedure of welding the conductive electrodes thereof on the electrical conductor mentioned above. Thus, the present disclosure keeps away from disadvantages of welding the conductive electrodes of the AC driven LED package element on the electrical conductor mentioned above.

Therefore, the AC driven LED light apparatus includes a support, two conductive wires and an AC driven LED package element. The conductive wires are served for conducting an external power of alternating current. The AC driven LED package element has a heat sinking substrate, a chip set, two conductive electrodes and a package body. The heat sinking substrate has one fixing flange extended from a rim of the heat sinking substrate, and the fixing flange is served for fixing the heat sinking substrate on the support. The chip set is disposed on the heat sinking substrate and has one AC driven LED chip. The conductive electrodes are respectively set at two opposite sides of the heat sinking substrate. Each of the conductive electrodes has one end thereof electrically connected to the AC driven LED chip, and the other end thereof detachably and electrically connected to one of the conductive wires. The package body envelops the heat sinking substrate, the chip set and a part of the conductive electrodes to be one together.

According to an embodiment of the present disclosure, the heat sinking substrate and each of the fixing flanges are formed integrally.

According to another embodiment of the present disclosure, each fixing flange is extended outwards the rim of the heat sinking substrate horizontally or vertically.

According to the other embodiment of the present disclosure, each fixing flange is shaped as a plate or a pillar.

According to the other embodiment of the present disclosure, each fixing flange has a first fastening portion, and the support has a plurality of second fastening portions. Each of the first fastening portions and each of the second fastening portions are fit and coupled with each other. The first fastening portion, for example, can be a post for being fixed by an aperture, an aperture for being fixed by a post, or a hook for being fixed by a post.

According to the other embodiment of the present disclosure, the conductive electrodes are respectively shaped as a plate or a pillar, and remain a distance from the support.

According to the other embodiment of the present disclosure, each of the conductive electrodes has a first stopper, and each of the conductive wires has a second stopper fit and coupled with the first stopper. Thus, each conductive electrode is fixed by the corresponding conductive wire.

Therefore, since the assembly procedure of the AC driven LED light package element employs a non-welding method for electrically connecting the AC driven LED chips and the external power of alternating current, rather than a welding method. Thus, the present disclosure has advantages as follows.

1. Because the assembly procedure of the AC driven LED package element employs the welding method no more, the assembly work of the AC driven LED package element eliminates the welding process from the assembly procedure thereof, so as to further save assembling time, manpower and the assembling cost.

2. Because the assembly procedure of the AC driven LED package element employs the welding method no more, thus, when the AC driven LED package element needs to be repaired or replaced, the AC driven LED package element can be removed from the AC driven LED light apparatus directly so as to improve the convenience and the flexibility.

3. Because the assembly procedure of the AC driven LED package element employs the welding method no more, the failure possibility of making the AC driven LED package element will be cut down once the AC driven LED package element does not need to pass through the solder oven. Furthermore, the maker of the AC driven LED package element does not need to put components having thermo protection characteristics, so as to simplify the structure of the product and decrease the material cost.

4. Because the assembly procedure of the AC driven LED package element employs the welding method no more, it allows workers who are unfamiliar with the welding process to easily detach or assemble the AC driven LED package element.

To sum, in view of the above advantages, the elimination of the welding process from the assembly procedure is quite worthy in this disclosure. Furthermore, since the AC driven LED package element electrically connects with the AC power supply, the AC driven LED package element does not need additional converting circuits.

### BRIEF DESCRIPTION OF THE DRAWINGS

FIG. 1 illustrates a 3D perspective view of a conventional AC driven LED package structure.

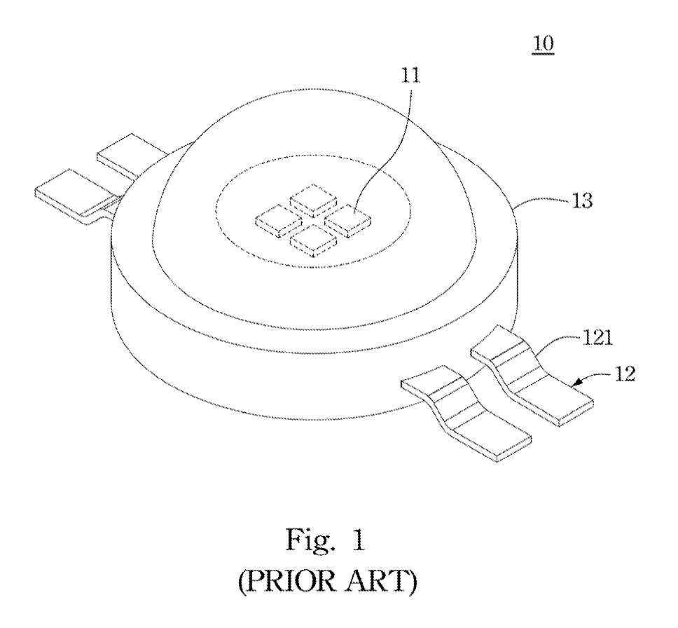

FIG. 2 illustrates an interior schematic diagram of an AC driven LED light apparatus according to an embodiment of the disclosure.

FIG. 3 illustrates an exploded view of an AC driven LED package element according to the embodiment of the disclosure.

FIG. 4 illustrates another interior schematic diagram of an AC driven LED light apparatus according to another embodiment of the disclosure.

FIG. 5 illustrates the other interior schematic diagram of an AC driven LED light apparatus according to the other embodiment of the disclosure.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The present disclosure is to provide an AC driven light emitting diode (AC driven LED) light apparatus, and its AC driven LED package element therein, in which the AC driven LED light apparatus employs non-welding method (e.g. detachably coupling with conductive wires) for electrically connecting the AC driven LED package element and the electrical conductor, so as to replace the welding method of connection, thus, to keep away from the disadvantages of the welding method mentioned above.

Meanwhile, since the assembly procedure of the AC driven LED package element does not employ the welding method for connection, the disclosure adds a fixing mechanism for fixing the AC driven LED package element on the AC driven LED light apparatus.

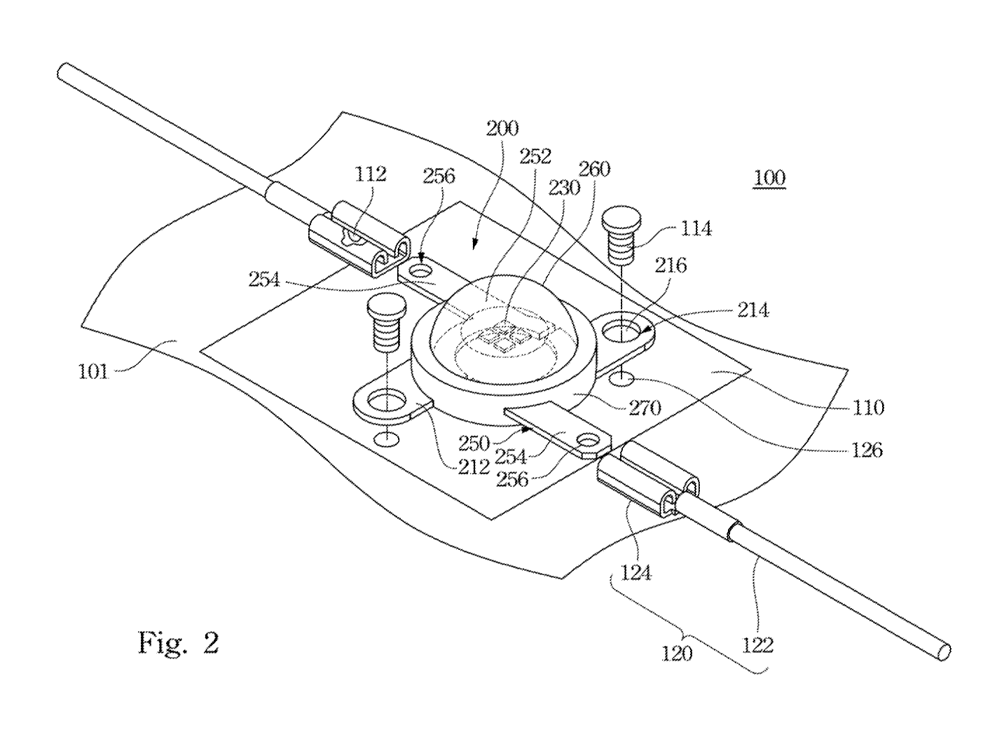

Refer to FIG. 2. FIG. 2 illustrates an interior schematic diagram of an AC driven LED light apparatus according to an embodiment of the disclosure. The AC driven LED light apparatus 100 at least includes a light body 101, a support 110, two conductive wires 120 and an AC driven package element 200. The support 110 is disposed on the light body 101. The AC driven package element 200 is disposed on the support 110 and electrically connected to the AC electricity wires 120.

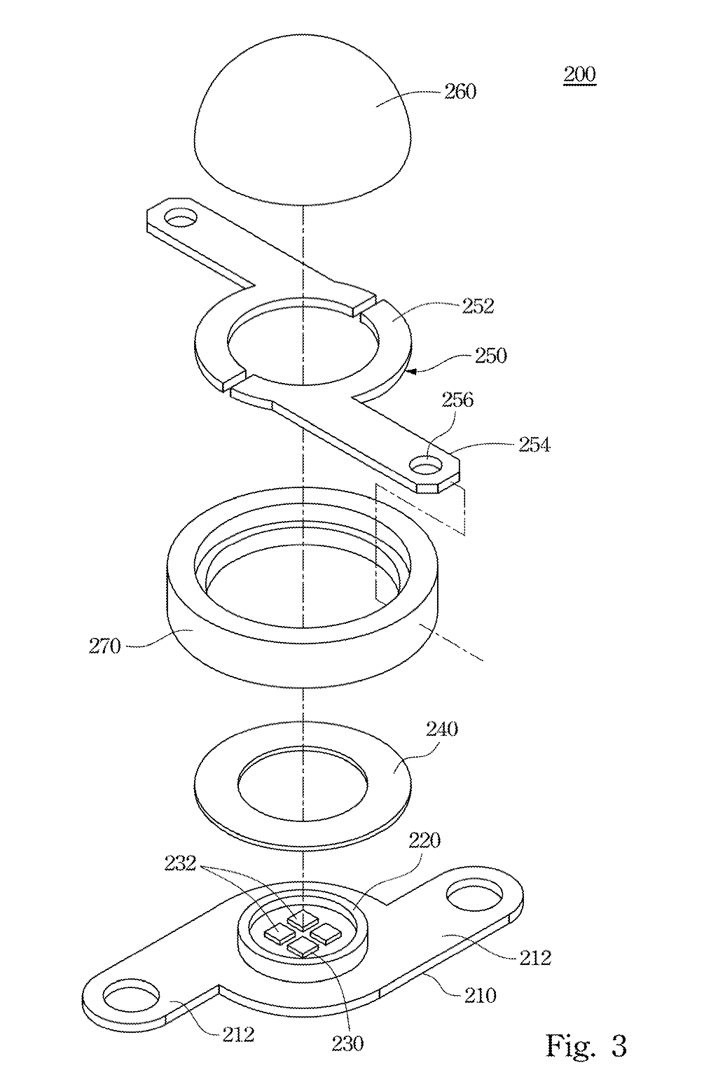

Refer to FIG. 3. FIG. 3 illustrates an exploded view of an AC driven LED package element according to the embodiment of the disclosure. In the embodiment, following a direction from a bottom of the AC driven package element 200, a middle of the AC driven package element 200 to a top of the AC driven package element 200, the AC driven package element 200 has a heat sinking substrate 210, a cup-shaped holder 220, a chip set 230, an insulating washer 240, two conductive electrodes 250 and a lens 260 in sequence, and the AC driven package element 200 also has a package body 270 to envelop them together to be one integrally.

The heat sinking substrate 210 has a plurality of fixing flanges 212 extended from a rim of the heat sinking substrate 210. Those fixing flanges 212 are served for fixing the heat sinking substrate 210 on the support 110 (FIG. 2). Alternatively, those fixing flanges 212 can be chosen to form on the heat sinking substrate 210 integrally or not.

The cup-shaped holder 220 is disposed on one surface of the heat sinking substrate 210, and has a space therein for holding the chip set 230. The chip set 230 includes a plurality of AC driven LED chips 232 mounted on the cup-shaped holder 220. The insulating washer 240 is disposed on the heat sinking substrate 210, has a circular ring shape having an opening therein for being gone through by the cup-shaped holder 220.

Each of the conductive electrodes 250 has a first end 252 and a second end 254 which are opposite with each other. The first end 252 of the conductive electrodes 250 is arranged on one side of the insulating washer 240, which is opposite to the heat sinking substrate 210, and the first end 252 of the conductive electrodes 250 is neighboring to the cup-shaped holder 220. In detail, exemplarily, the first end 252 of the conductive electrodes 250 can be shaped to match the surface of the cup-shaped holder 220, and the first end 252 of the conductive electrodes 250 can be electrically connected with the AC driven LED chips 232 via some bonding wires. The second end 254 of the conductive electrodes 250 is away from the cup-shaped holder 220, and extended outwards the package body 270. The second end 254 of the conductive electrodes 250 can be detachably and electrically connected with one of the AC electricity wires 120. The lens 260 covers the cup-shaped holder 220 and each first end 252 of the conductive electrodes 250.

The package body 270 is formed by injection molding plastic materials to wrap the circumference of the lens 260, the cup-shaped holder 220, the insulating washer 240, the heat sinking substrate 210, and each first end 252 of the conductive electrodes 250 before the plastic materials are solidified. Thus, the package body 270 envelops the heat sinking substrate 210, the chip set 230, and the conductive electrodes 250 to be one integrally, but exposes the lens 260, the fixing flange 212 and the second ends 254 of the conductive electrodes 250.

Therefore, because of the fixing flanges 212, the AC driven package element 200 can be installed stably on the support 110 without welding method for connection. Also, when the conductive electrodes 250 are respectively electrically connected with the corresponding AC electricity wire 120, the light body 101 remains in electrical connection with an AC electric power.

Since the assembly procedure of the AC driven LED package element 200 does not employ the welding method for installing the AC driven LED package element 200 on the light body 101, the conductive electrodes 250 can be detachably and electrically connected with the AC electricity wires 120 of the AC driven LED light apparatus 100.

Return to FIG. 2 again. According to the embodiment, each of the conductive electrodes 250, or at least the second end 254 of the conductive electrodes 250, is shaped as a plate or a pillar. The conductive electrodes 250 or the second ends 254 thereof respectively remain a certain distance from the support 110 which the heat sinking substrate 210 is placed on.

Furthermore, in order to quick join the conductive electrode 250 and the AC electricity wires 120 together, both the second end 254 of the conductive electrode 250 and the AC electricity wires 120 have a quick linked connector (or called Quick Terminal) which are fit with each other.

Each of the AC electricity wires 120 includes a cable body 122 and a connector 124. The cable body 122 is electrically connected with an AC electricity power source with one end thereof. The connector 124 is set on another end of the cable body 122, and capable of detachably connecting or disconnecting the second end 254 of the conductive electrode 250 rapidly. The connector 124, for example, can be a flat connector, a clip connector and alike. However, the variety of the connectors 124 is not limited into the disclosure.

Specifically, the second end 254 of the conductive electrode 250 has a first stopper 256, e.g. a depressing hole or a protrudent block. The connector 124 of the AC electricity wires 120 has a second stopper 112, e.g. a protrudent block or a depressing hole. The second stopper 112 is fit with the first stopper 256 for coupling the first stopper 256.

Moreover, the quantity, the appearance or the position of the fixing flanges 212 mentioned above is not restricted in this disclosure, as long as the fixing flanges 212 are characterized to secure the AC driven LED package element 200. For example, the quantity of the fixing flanges 212 mentioned above can be one, two, three, four or more; or the appearance of the fixing flanges 212 mentioned above can be straight, non-straight, plated, or pillared; or the position of the fixing flanges 212 mentioned above can be extended horizontally or vertically outwards from the heat sinking substrate 210.

Particularly, in order to effectively secure the AC driven LED package element 200 on the light body 101, the fixing flange 212 has at least one first fastening portion 214, and the support 110 also has at least one second fastening portion 126 corresponding to the first fastening portions 214 and fitting with the first fastening portion 214 for coupling the first fastening portion 214.

The first fastening portion 214, for example, can be a post (not shown) served for being fixed in an aperture, or can be an aperture 216 (FIG. 2) served for being fixed on a post as a bolt 114. Thus, by engaging the first fastening portion 214 on the second fastening portion 126, the AC driven LED package element 200 can be fixed on the light body 101.

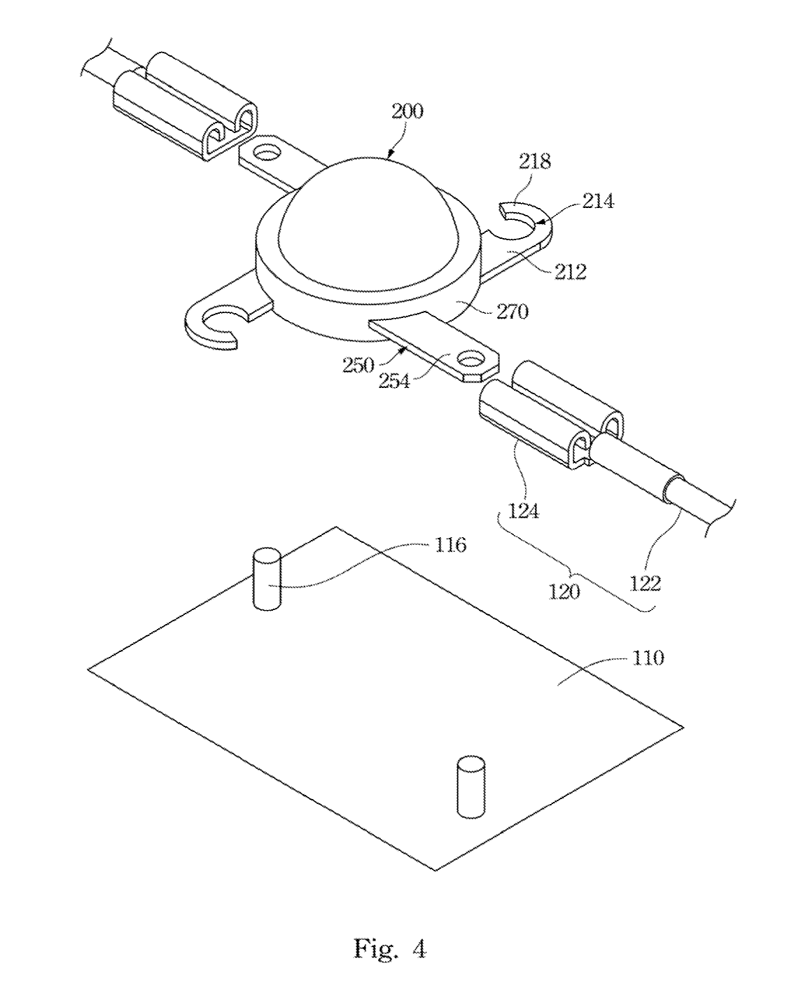

FIG. 4 illustrates another interior schematic diagram of an AC driven LED light apparatus according to another embodiment of the disclosure. Another embodiment of the first fastening portion 214, for example, can be a hook 218 served for being fixed with a protrudent block 116. Thus, by rotating the AC driven LED package element 200, the hooks 218 are moved to hook the corresponding protrudent blocks 116, respectively, and then the AC driven LED package element 200 can be fixed on the light body 101.

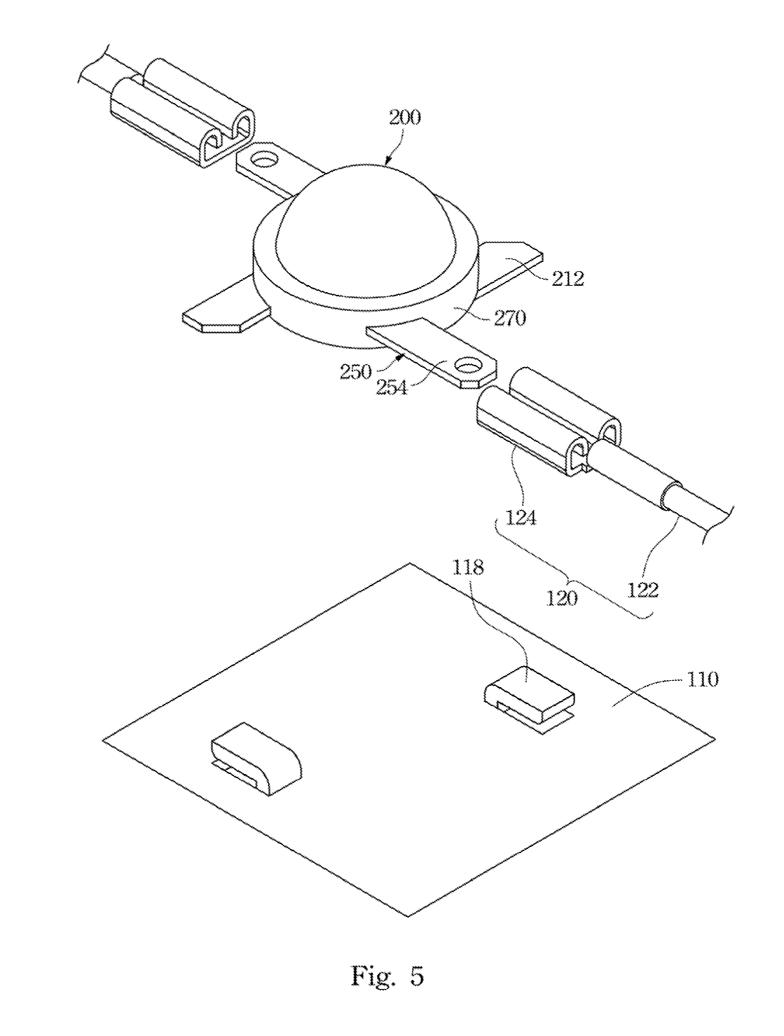

FIG. 5 illustrates the other interior schematic diagram of an AC driven LED light apparatus according to the other embodiment of the disclosure. Furthermore, the other embodiment of the second fastening portion 126, for example, can be a tenon 118 served for being fixed with one of the fixing flanges 212. Thus, by rotating the AC driven LED package element 200, one side of all of the fixing flanges 212 contacts against the corresponding tenon 118. Therefore, the AC driven LED package element 200 can be fixed on the light body 101 without bolts.

Next, a method of assembling the AC driven LED package element 200 on the light body 101 (FIG. 2) is disclosed in the disclosure, the method comprises steps of:

(1) Firstly, placing the AC driven LED package element 200 on the support 110 with the heat sinking substrate 210 (FIG. 3), and the heat sinking substrate 210 lies flat on a heat sinking area of the support 110;

(2) Next, by engaging the first fastening portion 214 with the second fastening portion 126, the AC driven LED package element 200 is stably fixed on the support 110. When the first fastening portion 214 is as the hook 218 mentioned above exemplarily (FIG. 4), each hook 218 of the fixing flanges 212 can be moved to hook the corresponding protrudent block 116 for fixing the AC driven LED package element 200 on the support 110, when rotating the AC driven LED package element 200.

(3) Then, by joining the second stopper 112 of the connector 124 to the first stopper 256 of the conductive electrodes 250 respectively, the second ends 254 of the conductive electrodes 250 are coupled with the AC electricity wires 120 of the AC driven LED light apparatus 100. Thus, as long as the AC electricity wires 120 cannot be easy to release from the conductive electrodes 250, the method of assembling the AC driven LED package element 200 on the light body 101 is therefore finished.

Finally, it needs to be noted that the support 110 can be any part of the light body 101 which installs the heat sinking substrate 210 for fixing the AC driven LED package element 200 thereon. Therefore, when the support 110 has a good heat sinking property, heat produced from the AC driven LED package element 200 can be passed out from the support 110 via the heat sinking substrate 210.

Therefore, since the AC driven LED light package element 200 is installed on the light body 101 by a non-welding method, thus, the present disclosure has advantages as follows.

1. Simplifying the assembly procedure thereof to further save the assembling time, the manpower and the assembling cost thereof.

2. Improving the convenience and the flexibility when the AC driven LED package element can be removed from the AC driven LED light apparatus directly for maintaining or replacing the AC driven LED light package element 200.

3. Decreasing the failure possibility of the AC driven LED light package element 200 from the high temperature of the solder oven.

4. Decreasing the difficulty of detaching or assembling the AC driven LED light package element 200 on the light body 101.

To sum, in view of the above advantages, the elimination of the welding process from the assembly procedure is quite worthy in this disclosure. Furthermore, since the AC driven LED package element electrically connects with the AC power supply, the AC driven LED package element does not need additional converting circuits.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. Alternating current driven light emitting diode (AC driven LED) package element, comprising:
a heat sinking substrate having at least one fixing flange extended from a rim of the heat sinking substrate and served for fixing the heat sinking substrate on a support;
a chip set disposed on the heat sinking substrate and having at least one AC driven LED chip;
two conductive electrodes respectively set at two opposite sides of the heat sinking substrate, wherein each of the conductive electrodes has one end thereof electrically connected to the AC driven LED chip, and the other end thereof detachably and electrically connected to a AC electricity wire; and
a package body enveloping the heat sinking substrate, the chip set and a part of the conductive electrodes to be one.

2. The alternating current driven light emitting diode (AC driven LED) package element according to claim 1, wherein the heat sinking substrate and the fixing flange are formed integrally.

3. The alternating current driven light emitting diode (AC driven LED) package element according to claim 1, wherein the fixing flange is extended outwards the rim of the heat sinking substrate horizontally.

4. The alternating current driven light emitting diode (AC driven LED) package element according to claim 1, wherein the fixing flange is extended outwards the rim of the heat sinking substrate vertically.

5. The alternating current driven light emitting diode (AC driven LED) package element according to claim 1, wherein the fixing flange is shaped as a plate or a pillar.

6. The alternating current driven light emitting diode (AC driven LED) package element according to claim 1, wherein the fixing flange has a fastening portion.

7. The alternating current driven light emitting diode (AC driven LED) package element according to claim 6, wherein the fastening portion is a post for being fixed by an aperture, an aperture for being fixed by a post, or a hook for being fixed by a post.

8. The alternating current driven light emitting diode (AC driven LED) package element according to claim 1, wherein each of the conductive electrodes is shaped as a plate or a pillar.

9. Alternating current driven light emitting diode (AC driven LED) package element, comprising:
a package body;
a heat sinking substrate positioned on a bottom of the package body, and only exposing at least one fixing flange from the package body, wherein the fixing flange is integrally extended from a rim of the heat sinking substrate;
two conductive electrodes positioned on a middle of the package body, and having a first end and a second end opposite with each other, wherein the first end is arranged in the package body, and the second end thereof extending outwards from the package body for electrically connecting to an AC electricity wire; and
a lens positioned on a top of the package body, and partially exposed from the package body.

10. The alternating current driven light emitting diode (AC driven LED) package element according to claim 9, wherein the fixing flange is extended outwards the rim of the heat sinking substrate horizontally.

11. The alternating current driven light emitting diode (AC driven LED) package element according to claim 9, wherein the fixing flange is extended outwards the rim of the heat sinking substrate vertically.

12. The alternating current driven light emitting diode (AC driven LED) package element according to claim 9, wherein the fixing flange is shaped as a plate or a pillar.

13. The alternating current driven light emitting diode (AC driven LED) package element according to claim 9, wherein the fixing flange has a fastening portion.

14. The alternating current driven light emitting diode (AC driven LED) package element according to claim 13, wherein the fastening portion is a post for being fixed by an aperture, an aperture for being fixed by a post, or a hook for being fixed by a post.

15. The alternating current driven light emitting diode (AC driven LED) package element according to claim 9, wherein each of the conductive electrodes is shaped as a plate or a pillar.

16. Alternating current driven light emitting diode (AC driven LED) light apparatus, comprising:
a support;
two AC electricity wires for conducting an external power of alternating current; and
an alternating current driven light emitting diode (AC driven LED) package element, comprising:
a heat sinking substrate having at least one fixing flange extended from a rim of the heat sinking substrate and served for fixing the heat sinking substrate on the support;
a chip set disposed on the heat sinking substrate and having at least one AC driven LED chip; and
two conductive electrodes respectively set at two opposite sides of the heat sinking substrate, wherein each of the conductive electrodes has one end thereof electrically connected to the AC driven LED chip, and the other end thereof detachably and electrically connected to one of the AC electricity wires.

17. The alternating current driven light emitting diode (AC driven LED) light apparatus according to claim 16, wherein the fixing flange has at least one first fastening portion, and the support has at least one second fastening portion fit with the first fastening portion for coupling the first fastening portion.

18. The alternating current driven light emitting diode (AC driven LED) light apparatus according to claim 17, wherein the first fastening portion is a post for being fixed by an aperture, an aperture for being fixed by a post, or a hook for being fixed by a post.

19. The alternating current driven light emitting diode (AC driven LED) light apparatus according to claim 17, wherein the second fastening portion is a tenon.

20. The alternating current driven light emitting diode (AC driven LED) light apparatus according to claim 16, wherein each of the conductive electrodes has a first stopper, and each of the AC electricity wires has a second stopper fit with the first stopper for coupling the first stopper.
